(19) United States
(12) Patent Application Publication
(10) Pub. No.: US 2002/0046849 A1
(43) Pub. Date: Apr. 25, 2002

(54) Methods and apparatus for EMI shielding

(76) Inventors: Martin L. Rapp, Grover, MO (US); Reed Niederkorn, St. Louis, MO (US); Paul Stus, Sycomore Hills, MO (US); Larry Creasy, Lonedell, MO (US)

Correspondence Address: TESTA, HURWITZ & THIBEAULT, LLP, HIGH STREET TOWER, 125 HIGH STREET, BOSTON, MA, 02110, US

(21) Appl. No.: 09/768,428

(22) Filed: Jan. 24, 2001

Related U.S. Application Data
(60) Provisional application No. 60/178,517, filed on Jan. 24, 2000.

(51) Int. Cl. H05K 9/00

(52) U.S. Cl. 174/35 R

(57) ABSTRACT

Disclosed are methods for manufacturing electromagnetic interference shields for use around access panels and doors in electronic equipment enclosures and elsewhere. The shields may include an electrically nonconductive substrate in combination with an electrically conductive element. In one embodiment, the method may use vapor deposition, plating, or painting techniques for depositing a conductive layer on the substrate surface. In another embodiment the method may use foam-forming to intersperse conductive elements within the substrate. The conductive layer and conductive elements provide effective shielding and grounding functions, and the substrate provides elastic compliancy and resiliency to the shield.

### RELATED APPLICATIONS

This application claims priority to and incorporates herein by reference in its entirety U.S. Provisional Application Serial No. 60/178,517, filed on Jan. 24, 2000, entitled Method and Apparatus for EMI Shielding.

### FIELD OF THE INVENTION

This invention relates to methods of manufacturing electromagnetic interference (“EMI”) shields and the EMI shields produced thereby.

### BACKGROUND OF THE INVENTION

As used herein, the term EMI should be considered to refer generally to both EMI and radio frequency interference (“RFI”) emissions, and the term electromagnetic should be considered to refer generally to electromagnetic and radio frequency.

During normal operation, electronic equipment generates undesirable electromagnetic energy that can interfere with the operation of proximately located electronic equipment due to EMI transmission by radiation and conduction. The electromagnetic energy can be of a wide range of wavelengths and frequencies. To minimize the problems associated with EMI, sources of undesirable electromagnetic energy may be shielded and electrically grounded. Shielding is designed to prevent both ingress and egress of electromagnetic energy relative to a housing or other enclosure in which the electronic equipment is disposed. Since such enclosures often include gaps or seams between adjacent access panels and around doors, effective shielding is difficult to attain, because the gaps in the enclosure permit transference of EMI therethrough. Further, in the case of electrically conductive metal enclosures, these gaps can inhibit the beneficial Faraday Cage Effect by forming discontinuities in the conductivity of the enclosure which compromise the efficiency of the ground conduction path through the enclosure. Moreover, by presenting an electrical conductivity level at the gaps that is significantly different from that of the enclosure generally, the gaps can act as slot antennae, resulting in the enclosure itself becoming a secondary source of EMI.

Specialized EMI gaskets have been developed for use in gaps and around doors to provide a degree of EMI shielding while permitting operation of enclosure doors and access panels. To shield EMI effectively, the gasket should be capable of absorbing or reflecting EMI as well as establishing a continuous electrically conductive path across the gap in which the gasket is disposed. Conventional metallic gaskets manufactured from copper doped with beryllium are widely employed for EMI shielding due to their high level of electrical conductivity. Due to inherent electrical resistance in the gasket, however, a portion of the electromagnetic field being shielded induces a current in the gasket, requiring that the gasket form a part of an electrically conductive path for passing the induced current flow to ground. Failure to ground the gasket adequately could result in radiation of an electromagnetic field from a side of the gasket opposite the primary EMI field.

In addition to the desirable qualities of high conductivity and grounding capability, EMI gaskets in door applications should be elastically compliant and resilient to compensate for variable gap widths and door operation, yet tough to withstand repeated door closure without failing due to metal fatigue, compression set, or other failure mechanism. EMI gaskets should also be configured to ensure intimate electrical contact with proximate structure while presenting minimal force resistance per unit length to door closure, as the total length of an EMI gasket to shield a large door can readily exceed several meters. It is also desirable that the gasket be resistant to galvanic corrosion which can occur when dissimilar metals are in contact with each other for extended periods of time. Very low resistance and, concomitantly, very high electrical conductivity are becoming required characteristics of EMI gaskets due to increasing shielding requirements. Low cost, ease of manufacture, and ease of installation are also desirable characteristics for achieving broad use and commercial success.

Conventional metallic EMI gaskets, often referred to as copper beryllium finger strips, include a plurality of cantilevered or bridged fingers forming linear slits therebetween. The fingers provide spring and wiping actions when compressed. Other types of EMI gaskets include closed-cell foam sponges having metallic wire mesh knitted thereover or metallized fabric bonded thereto. Metallic wire mesh may also be knitted over silicone tubing. Strips of rolled metallic wire mesh, without foam or tubing inserts, are also employed.

One problem with metallic finger strips is that to ensure a sufficiently low door closure force, the copper finger strips are made from thin stock, for example on the order of about 0.05 mm (0.002 inches) to about 0.15 mm (0.006 inches) in thickness. Accordingly, sizing of the finger strip uninstalled height and the width of the gap in which it is installed should be controlled to ensure adequate electrical contact when installed and loaded, yet prevent plastic deformation and resultant failure of the strip due to overcompression of the fingers. To enhance toughness, beryllium is added to the copper to form an alloy; however, the beryllium adds cost and is a concern since beryllium is considered to be carcinogenic. Due to their thinness, the finger strips are fragile and can fracture if mishandled or overstressed. Finger strips also have thin sharp edges, which are a safety hazard to installation and maintenance personnel. Finger strips are also expensive to manufacture, in part due to the costs associated with procuring and developing tooling for outfitting presses and rolling machines to form the complex contours required. Changes to the design of a finger strip to address production or performance problems require the purchase of new tooling and typically incur development costs associated with establishing a reliable, high yield manufacturing process. Notwithstanding the above limitations, metallic finger strips are commercially accepted and widely used. Once manufacturing has been established, large quantities of finger strips can be made at relatively low cost.

Another problem with conventional finger strips is that they are not as effective in EMI shielding as clock speed of an electronic product is increased. As clock speed is increased, the wavelength of the EMI waves produced decreases. Accordingly, the waves can penetrate smaller and smaller apertures in the enclosure and in the EMI shield. At lower wavelengths, the slits formed in the finger shields can act as slot antennae, permitting the passage of EMI therethrough and the resultant shielding effectiveness of the shields decreases. Conventional finger strips with linear slits formed between the fingers are increasingly less effective in these applications.

Metallized fabric covered foam gaskets avoid many of the installation, performance, and safety disadvantages of finger strips; however, they can be relatively costly to produce due to expensive raw materials. Nonetheless, EMI gaskets manufactured from metallized fabrics having foam cores are increasing in popularity, especially for use in equipment where performance is a primary consideration.

As used herein, the term metallized fabrics include articles having one or more metal coatings disposed on woven, nonwoven, or open mesh carrier backings or substrates and equivalents thereof. See, for example, U.S. Pat. No. 4,900,618 issued to O'Connor et al., U.S. Pat. No. 4,910,072 issued to Morgan et al.; U.S. Pat. No. 5,075,037 issued to Morgan et al., and U.S. Pat. No. 5,393,928 issued to Cribb et al., the disclosures of which are herein incorporated by reference in their entirety. Metallized fabrics are commercially available in a variety of metal and fabric carrier backing combinations. For example, pure copper on a nylon carrier, nickel-copper alloy on a nylon carrier, and pure nickel on a polyester mesh carrier are available under the registered trademark Flectron® metallized materials from Advanced Performance Materials located in St. Louis, Mo. An aluminum foil on a polyester mesh carrier is available from Neptco, located in Pawtucket, R.I.

The choice of metal is guided, in part, by installation conditions of the EMI shield. For example, a particular metal might be chosen due to the composition of abutting body metal in the enclosure to avoid galvanic corrosion of the EMI shield, which could increase electrical resistance and deteriorate electrical grounding performance. Metallized tapes are desirable both for ease of application as well as durability.

Metallized fabrics, such as those described in the O'Connor et al. patent mentioned hereinabove, are generally made by electroless plating processes, such as electroless deposition of copper or other suitable metal on a catalyzed fiber or film substrate. Thereafter one or more additional layers of metal, such as nickel, may be electrolessly or electrolytically deposited on the copper. These additional layers are applied to prevent the underlying copper layer from corroding, which would increase the resistance and thereby decrease the electrical conductivity and performance of any EMI gasket made therefrom. The additional nickel layer on the copper also provides a harder surface than the base copper.

There exist, however, a number of shortcomings with electroless on electroless layered metallized fabrics. For example, there is relatively high chemical usage and associated costs with electroless deposition processes. There is also waste generation. Accordingly, the deposition process lines must be shut down frequently so that the tanks and other process line equipment can be cleaned properly, which effects on-stream production time. Additionally, the waste must be disposed of in an environmentally safe manner. There are also practical limits of minimum electrical resistivity, which are challenged by increasingly demanding performance requirements.

Accordingly, there is a need in the art for EMI gaskets which exhibit very low resistance and avoid the shortcomings of conventional EMI gaskets. Additionally, there is a need in the art for alternative EMI gaskets, which are compliant, resilient, and inherently conductive.

### SUMMARY OF THE INVENTION

The present invention relates to EMI gaskets or shields and, more specifically, to EMI shields manufactured by any of a variety of processes from a combination of electrically conductive or nonconductive, compliant, resilient material substrates covered with or containing electrically conductive elements.

For example, suitable substrates include reticulated foams, piles, silicones, metal wools, thermoplastic elastomers, plastics, urethane foams, and other suitable materials. Conductive elements include thin metals, metal particles, shredded foils, shredded or unshredded metallized films, wires, flakes, sintered metals, grids, springs, carbon, conductive polymers, and other suitable materials. Processes to combine the substrates and conductive elements include sputtering, evaporation, electrolytic plating, electroless plating, painting, gluing, casting, co-precipitation (e.g., reduction from the salt into a foam matrix), and other suitable processes. See, for example U.S. Pat. No. 5,480,929 issued to Migala. As will be understood by those skilled in the art, any and all combinations and permutations of these substrates, conductive elements, and processes may be employed, as necessary and desirable, to produce EMI shields.

In general, in one aspect, this invention relates to a method of manufacturing an EMI shield. The method includes providing a substrate such as a foam, silicone, thermoplastic elastomer, or urethane foam with a substantially non-porous skin. The method further includes applying a conductive layer to the substrate using a vapor deposition process, an electroplating process, or a painting process. Finally, the coated substrate is cut to a desired shape to produce the EMI shield.

In another aspect, this invention relates to another method of manufacturing an EMI shield. The method includes providing a metal wool web. A foamable mixture is applied to the metal wool web, wherein the viscosity of the foamable mixture is sufficiently low and controlled so the foamable mixture permeates at least a portion of the metal wool web before substantial foaming of the foamable mixture begins. The metal wool web with the permeated foamable mixture is then cured and, following curing, the metal wool web with the cured permeated foamable mixture is then post-processed, as desired.

In yet another aspect, this invention relates to another method of manufacturing an EMI shield. The method includes the steps of mixing a polyol component and an isocyonate component with conductive particles to form a urethane foam mixture with an integral network of conductive particles. The urethane foam mixture with the integral network of conductive particles is then processed to shape the EMI gasket. In one embodiment the conductive particles may be silver-plated glass spheres, sintered metal particles, silver-plated copper particles, conductive polymers, and combinations thereof.

In yet another aspect, this invention relates to another method of manufacturing an EMI shield. This method includes providing a polymeric fiber fabric. The polymeric fiber fabric is then cleaned with an alkaline aqueous solution. Next, a catalytically active surface is created on the polymeric fiber fabric in order to allow electroless plating to be initiated. Then a surface of the polymeric fiber fabric is electrolessly plated in a suitable bath to a resistivity below about 10 ohms/sq.

The following additional United States patents, which are drawn to EMI shields and processes for manufacturing the shields according to the invention are incorporated herein by reference in their entirety: U.S. Pat. No. 4,102,033 issued to Emi, et al.; U.S. Pat. No. 4,968,854 issued to Benn, Sr., et al.; U.S. Pat. No. 5,068,493 issued to Benn, Sr., et al.; U.S. Pat. No. 5,082,734 issued to Vaughn; U.S. Pat. No. 5,107,070 issued to Benn, Sr., et al; U.S. Pat. No. 5,141,770 issued to Benn, Sr., et al; U.S. Pat. No. 5,318,855 issued to Glovatsky, et al.; U.S. Pat. No. 5,407,699 issued to Myers; U.S. Pat. No. 5,480,929 issued to Miyata; U.S. Pat. No. 5,489,489 issued to Swirbel, et al.; U.S. Pat. No. 5,696,196 issued to DiLeo; U.S. Pat. No. 5,804,912 issued to Park; and U.S. Pat. No. 6,013,203 issued to Paneccasio, Jr., et al.

### BRIEF DESCRIPTION OF THE DRAWINGS

The above and further advantages of this invention may be better understood by referring to the following description, taken in conjunction with the accompanying drawings, in which:

FIG. 1 is a process diagram of an embodiment of the current invention of a batch vapor deposition process for the manufacture of EMI shielding;

FIG. 2 is a process diagram of an embodiment of the current invention of a continuous vapor deposition process for the manufacture of EMI shielding;

FIG. 3 is a process diagram of an embodiment of the current invention of a plating process for the manufacture of EMI shielding;

FIG. 4 is a process diagram of an embodiment of the current invention of a conductive painting process for the manufacture of EMI shielding;

FIG. 5 is a process diagram of an embodiment of the current invention of a continuous foam-forming process for the manufacture of EMI shielding;

FIGS. 6A-6C are cross-sectional views of typical EMI shielding profiles from the process of FIG. 5;

FIG. 7 is a detailed enlarged view of the EMI shielding from the process of FIG. 5;

FIG. 8 is a process diagram of an embodiment of the current invention of another continuous foam-forming process for the manufacture of EMI shielding;

FIG. 9 is a cross-sectional view of the EMI shielding taken along line A-A in FIG. 8;

FIG. 10 is a process diagram of an embodiment of the current invention of a batch foam-forming process for the manufacture of EMI shielding;

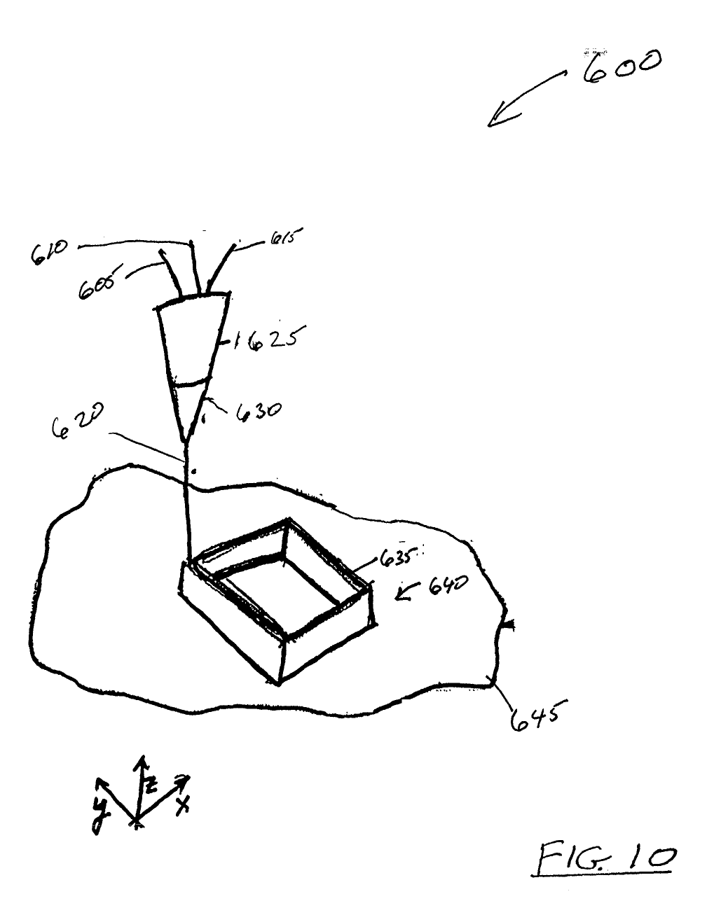

FIG. 11 is a table of substrates, conductive elements, and processes for manufacturing embodiments of the current invention; and

FIG. 12 is an enlarged view of an embodiment of the current invention of an EMI shield manufactured from a three dimensional knit polyester mono-filament.

### DETAILED DESCRIPTION OF THE INVENTION

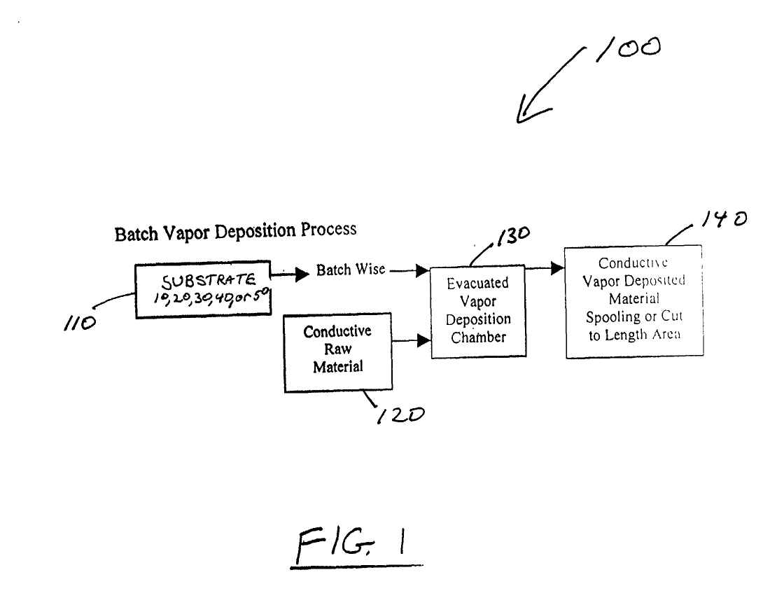

As shown generally in FIGS. 1-4, there are a variety of substrates 110 and processes that can be used to create a variety of EMI shields. Looking first at the substrates 110, any number of materials and configurations can be employed.

For example, in one embodiment, a silicone foam core 10 with a skin can be used as a substrate. The silicone foam core 10 with a skin is used to provide an environmental seal. The foam used in the silicone foam core 10 may be similar, but not limited to, foams made and distributed by Rogers Corporation located in Elk Grove Village, Ill. (product code numbers HT-800, BF-1000, etc.), Illbruck Incorporated, and Stockwell Rubber Company located in Philadelphia, Pa. (product code numbers R-10480-S, R-10480-M, S-10440-BL, R-10450-M, BF1000, F12, BF, etc.). A conductive layer is applied to the silicone foam core 10 by either a vapor deposition, a plating, or a painting process. The specific processes are described hereinbelow. The processes produce a non-elastomeric matrix. This gives the EMI shield the compression properties of foam, the environmental properties of a dense silicone extrusion, and the electrical properties of a metallized fabric.

In another embodiment, the substrate is a solid silicone 20, instead of a foam, resulting in a less compressible EMI shield, depending upon the properties of the substrate material used. Some examples of silicone 20 that can be used include, but are not limited to, those made and distributed by Rogers Corporation (product code numbers HT-820, HT-840, HT-1200, HT-2000, HT-6000, FPC, etc. ), Illbruck Incorporated, and Stockwell Rubber Company (product code numbers COHR 9275, SE60-RC, COHR 9050, COHR 9040, COHR-300, SE25-RS, etc.). A conductive layer is applied to the solid silicone 20 by vapor deposition, plating, or painting processes described below.

In another embodiment, the substrate is an extruded thermoplastic elastomer (“TPE”) foam profile 30, which may be similar, but not limited to, those extruded by Advanced Performance Materials for EMI shields, window seals extruded by Laird Security Systems Division of Laird Group Plc located in the United Kingdom, products made by Advanced Elastomer Systems L.P. located in Akron, Ohio or using their materials (e.g., product number: Santoprene 201-67W171 Thermoplastic Rubber), products made by DSM Thermoplastic Elastomers Inc. located in Saddle Brook, N.J., or using their materials (e.g., product number: Sarlink FR & LS Series, like XRD-3375B-07, XRD-3375B-071, XRD-3375B-072, XRD-3375N-07, XRD-439DB-03, XRD-439DB-06, etc.), and products generated or converted by Norton located in Wayne, N.J. (e.g., Norseal, Norex, Noroprene, Dynafoam, Normount, Thermalbond, T-Bond II, D.I.V.A., and Norfix). See, for example, U.S. Pat. Nos. 4,968,854, 5,068,493, 5,141,770, and 5,107,070. A conductive layer is applied to the TPE foam profile 30 by vapor deposition, plating, or painting processes, as described below.

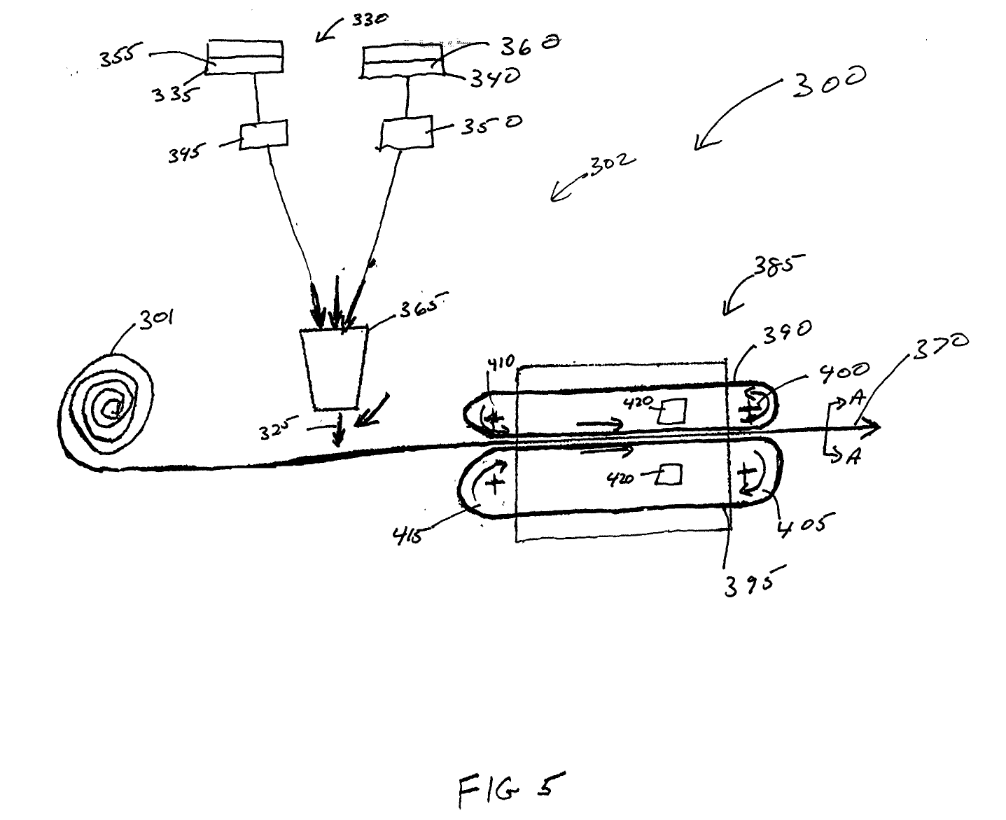

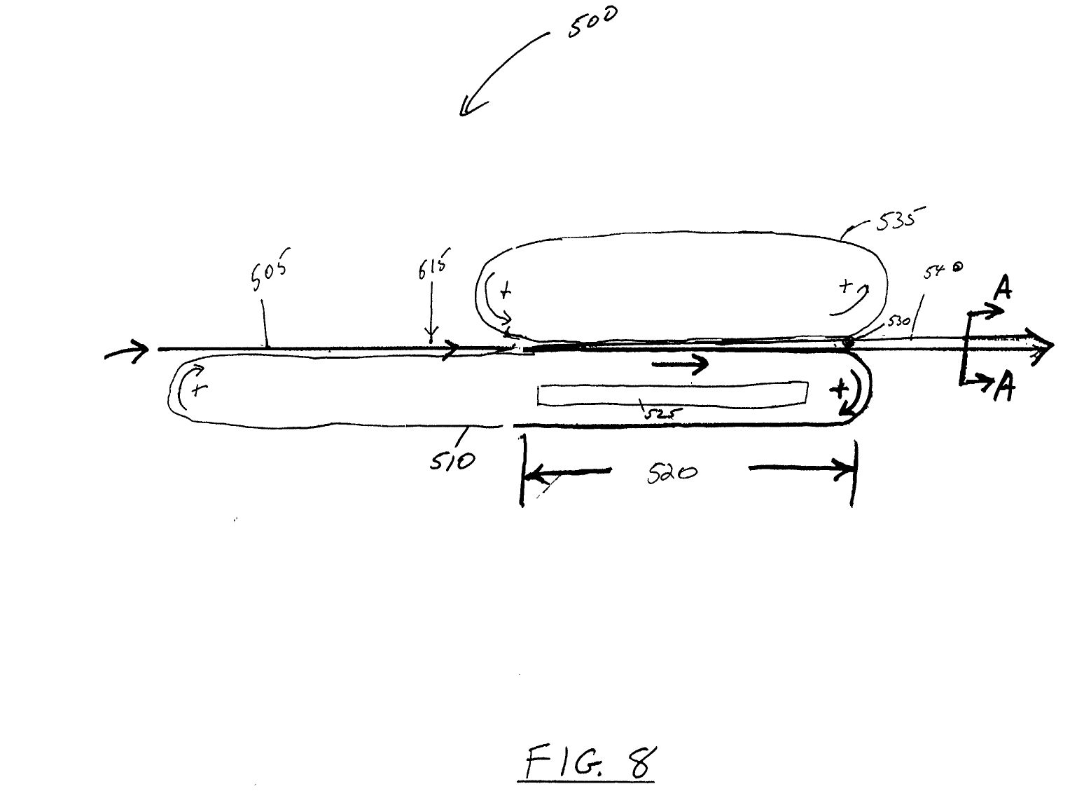

In yet another embodiment, the substrate can be a urethane foam profile 40 with a generally non-porous skin. The urethane foam profile 40 may be similar, but not limited to, those made via a continuous urethane extrusion (“CUE”) process discussed below and in U.S. patent application Ser. No. 09/627,582 entitled Method and Apparatus for Manufacturing a Flame Retardant EMI Gasket, the disclosure of which is herein incorporated by reference. Various isocyonates and polyols may be used. For example, modified diisocyonate compound (part number MDI ISO 7001) or toluene diisocyonate (part number TDI ISO 4001) may be used with polyol (part number FF3503XA6YSL) made by Plastomeric Inc., located in Sussex, Wis. Other polyols that may be used are Polystar C-33 polyol (sorbitol based) and Polystar C-62 polyol (amino based) by SWD Urethane Company located in Mesa, Ariz.; Naugard 445 Polyol by Uniroyal Co. located in Middlebury, Conn.; and Stepanpol PS 20-200A and PS 4002 polyol by Stephan Company. The material is extruded through a continuous process line, described with respect to FIGS. 5 and 8, and has a conductive layer applied thereto by vapor deposition, plating, or painting process described below. This metallized foam combination gives the very good compression properties of polyurethane foam and the electrical properties of a metallized fabric. This concept applies to other elastomer foams, as well.

In yet another embodiment, any of the above-referenced substrates are utilized, but the center of the profile is hollow, generally referred to herein as substrate 50. For example, these substrates 50 include the products made by Advanced Elastomer Systems L.P. or using their materials (e.g., product number: Santoprene 201-67W171 Thermoplastic Rubber) or by DSM Thermoplastic Elastomers Inc. or using their materials (e.g., product number: Sarlink FR & LS Series, like XRD-3375B-07, XRD-3375B-071, XRD-3375B-072, XRD-3375N-07, XRD-439DB-03, XRD-439DB-06, etc.). A conductive layer is applied thereto by vapor deposition, plating, or painting processes described below. The hollow metallized EMI gasket using this substrate 50 gives unique compression qualities normally not found in solid profiles.

Any one of the above mentioned substrates can be used with any of the following different processes to form an EMI shield. First, referring to FIG. 1, shown is a process for batch vapor deposition 100. A substrate 110, can be any one of the prior mentioned substrates 10, 20, 30, 40, and 50. Prior to vapor deposition, a surface of the substrate 110 is first treated or etched chemically (e.g., with acids between pH 1-7, such as hydrochloric acid or acetic acid, bases between pH 8-14, such as sodium hydroxide or ammonia, alcohols like isopropyl alcohol or methanol, and solvents like acetone or methyl ethyl ketone) or electrically (e.g., by corona treatment). The treated substrate 110 is then pulled or deposited into a vapor deposition chamber 130 which is evacuated. Conductive material 120 is vapor deposited on the substrate 110 in a way similar, but not limited to, those processes that put a relatively thin uniform layer of a substance (in this case conductive) on the substrate 110 using vapor deposition, such as the methods used by Vapor Technologies, Inc. located in Longmont, Colo., and The Coatings, Plating and Finishing Center at Oak Ridge Centers for Manufacturing Technology (ORCMT) located in Oak Ridge, Tenn. For example, see U.S. Pat. Nos. 5,318,855, 5,804,912, and 5,489,489. After the substrate 110 is coated with the vapor deposited conductive material, the substrate 110 is spooled or cut to length 140.

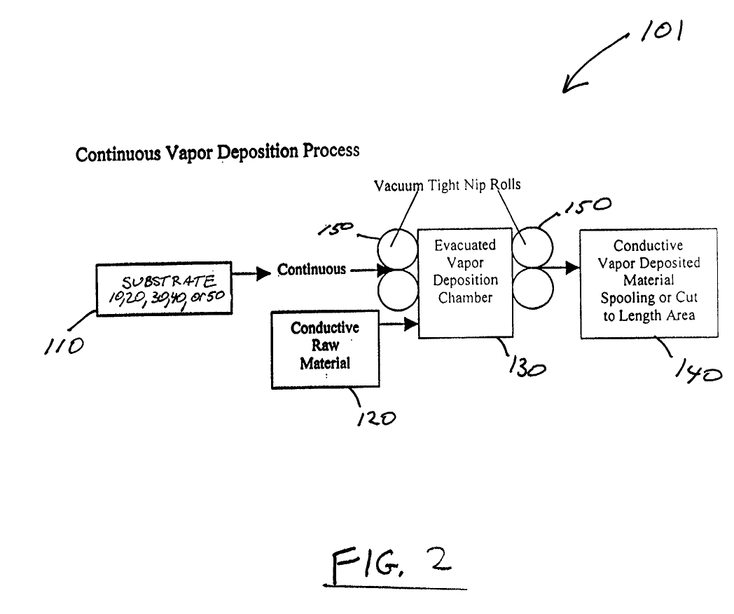

FIG. 2 illustrates a continuous vapor deposition process 101. In contrast to the batch vapor deposition process 100 shown in FIG. 1, this vapor deposition process 101 has vacuum tight nip rolls 150 to facilitate feeding the substrate 110 continuously into and out of the evacuated vapor deposition chamber 130, which allows a vacuum condition to be maintained in the vapor deposition chamber 130 at all times. As in the batch vapor deposition process 100 shown in FIG. 1, conductive raw material is vapor deposited onto the substrate 110 when the substrate is in the vapor deposition chamber 130. After the substrate 110 is vapor deposited with a conductive layer, the substrate 110 is spooled or cut to length 140.

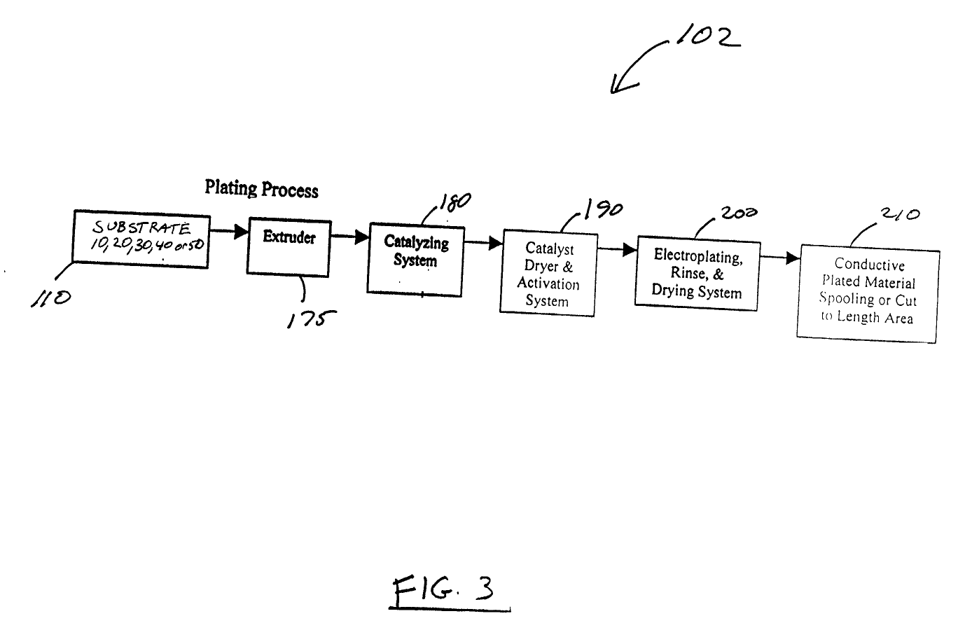

In yet another process 102, shown in FIG. 3, the substrate 110 is electroplated batch-wise or continuously by being pulled into a padder system containing a palladium based catalyst, as in U.S. Pat. No. 4,900,618. In one embodiment, the substrate 110 may pass through an extruder 175 prior to entering a catalyzing system 180. Any excess catalyst can be removed by a nip roll and/or brush system or other methods. The substrate 110 and catalyst is batch-wise or continuously activated and dried in an oven 190. At the exit of the oven 190, the substrate 110 is accumulated and combined (e.g., via stapling, taping, sewing, riveting, etc.). This material is then electrolessly and/or electrolytically plated 200 with a conductive metal layer using technology as in U.S. Pat. No. 5,082,734, or using commercially available electroplating systems/processes (e.g., those from OMG, McDermid, and/or Shipley). After the substrate 110 is coated, it is rinsed and dried 200, and later spooled or cut to length 210.

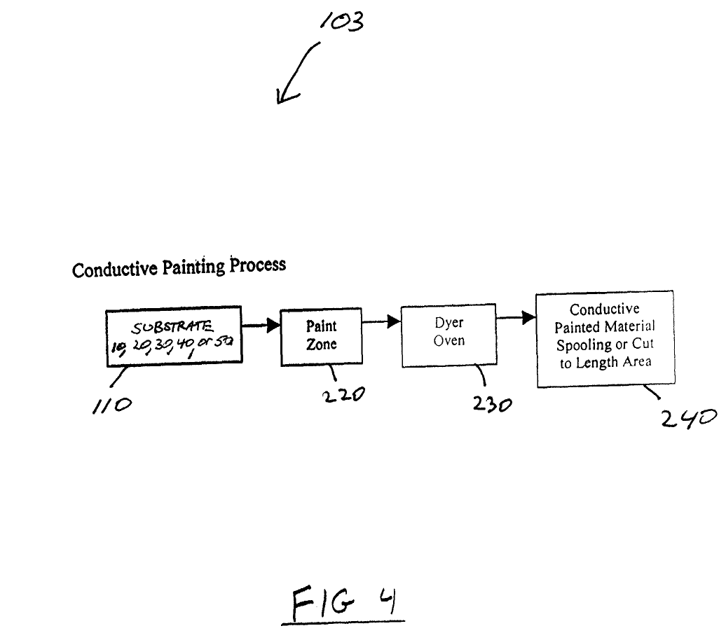

In yet another method 103, shown in FIG. 4, the substrate 110 is painted with a conductive layer, batch-wise or continuously, by pulling the substrate 110 past a spray zone 220 using commercial techniques (e.g., techniques similar to those used by Precision Painting Inc. located in St. Louis Mo.) or a brushing zone, a dipping/nipping zone, a rinsing zone, or an air gun spraying zone. For example, see U.S. Pat. Nos. 5,696,196 and 6,013,203. The conductive painted material is dried 230 and spooled or cut to length 240.

In another aspect, the invention relates to a method of manufacturing an EMI shield that has a conductive and compressible web. The EMI shield may be produced by starting with a web of metal wool, then foaming into this web any number of foamable polymer systems, to fill most or substantially all of the interstitial spaces, to encapsulate the metal wool, and to impart elastic, compliant, and resilient properties. See for example, U.S. patent application Ser. No. 09/627,582, entitled Method and Apparatus for Manufacturing a Flame Retardant EMI Gasket. This method may also be used with expanded metal grids.

FIG. 5 shows a process 300 for manufacturing an EMI shield by using a metal wool and a foamable polymer system. Spools of Stainless Steel Wool 301, Type 434, available from International Steel Wool Co. located in Springfield, Ohio, precut to the correct width, are unwound into the entry fixture of a continuous urethane extrusion “CUE” 302 machine available from APM, St. Louis, Mo. A urethane foam mixture for the EMI gasket can be produced by a using a chemical delivery system 330. In one embodiment, the chemical delivery system 330 has two tanks 335, 340 and two pumps 345, 350. The foam 325 is produced by mixing polyol 355 and isocyonate 360. The polyol 355 can be FE3503GY from Plast-O-Meric Incorporated of Sussex, Wis. The isocyonate 360 can be ISO 7000, also supplied by Plast-O-Meric Incorporated. The polyol 355 is stored in tank 335 and the isocyonate 360 is stored in tank 340. The polyol 355 and isocyonate 360 are pumped by respective pumps 345, 350 to a mix head 365 which has an internal beater which rotates to mix the polyol 355 and isocyonate 360 to create a chemical mixture 325 which foams after a time due to a chemical reaction process. The chemical mixture 325 is poured onto the stainless steel wool 301. The viscosity of the chemical mixture 325 is controlled so that the mixture permeates the stainless steel wool 301 before the foaming begins.

The stainless steel wool 301 and the chemical mixture 325 are passed through a heated dual belt mold 385. The heated belt mold 385 consists of two belts 390, 395, two drive pulleys 400, 405 and two follower pulleys 410, 415. The two belts 390, 395 form a continuous mold cavity of a desired dimension and profile for shaping the stainless steel wool 301 and the chemical mixture 325 while it expands. In one embodiment, the belts 390 and 395 can be made of rubber and in another embodiment the belts 390 and 395 can be made of thermoplastic resin. The chemical mixture 325 should be delivered to the heated belt mold 385 within the cream time of the mixture 325 to ensure the chemical mixture 325 enters the heated belt mold 385 prior to significant expansion, thereby allowing the chemical mixture 325 to penetrate the stainless steel wool 301. The heated belt mold 385 is heated by upper and/or lower heaters 420.

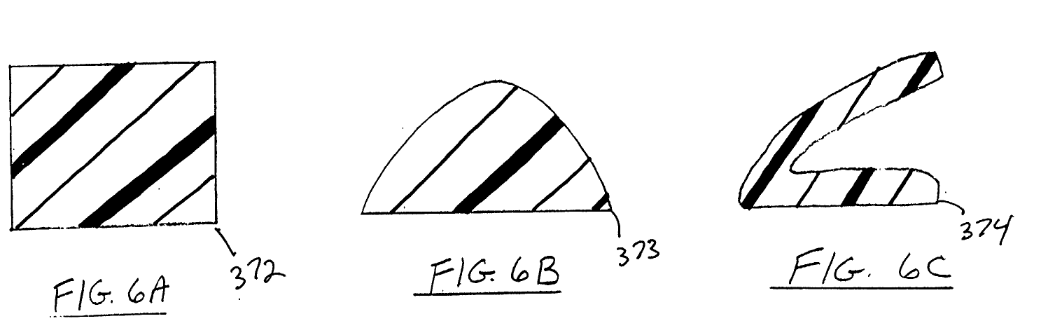

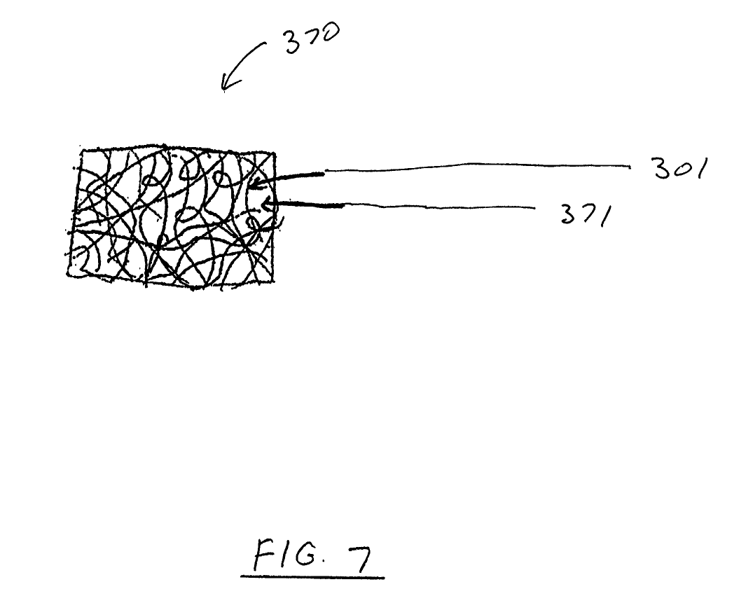

As the stainless steel wool 301 proceeds down the heated dual belt mold 385, the chemical mixture 325 foams and cures, thereby forming the desired profile shape. See, for example, FIGS. 6A-6C showing three simple profile shapes 372, 372, and 374. FIG. 7 shows cross-section A-A of the finished EMI web gasket 370 with a generally planar profile. The resulting cross-sectional profile contains a network of stainless steel fibers 301, such that good conductivity is attained in length, width, and thickness directions, and has a polyurethane supporting matrix 371, such that the product may be compressed significantly (e.g., up to about 80% or more) and rebounds, giving compression set of less than about 20% and preferably less than about 10%. The resultant EMI web gasket product 370 from the CUE machine can then be cut to the desired length, installation adhesive tape applied, if necessary, and further processed (e.g., die-cut), if required.

In another aspect, the invention relates to another method 500, shown in FIG. 8, of manufacturing an EMI shield that has a conductive and compressible web. According to this method 500, an unstructured nonwoven web 505 constructed of chopped metallized fibers (e.g., X-static fibers available from Sauquoit Company located in Scranton, Pa.) is fed onto a moving, wide (e.g., 1.5 meter) belt 510. A mixture of a foamable compound 515 (e.g., silicone foam) is dispensed across the entire unstructured nonwoven web 505, the viscosity of the foamable compound 515 being low enough to permit substantially complete permeation into the unstructured nonwoven web 505. The unstructured nonwoven web 505, containing the foamable compound 515, is conveyed to a curing section 520, where heat is optionally applied by a heater 525 to expand and cure the foamable compound 515.

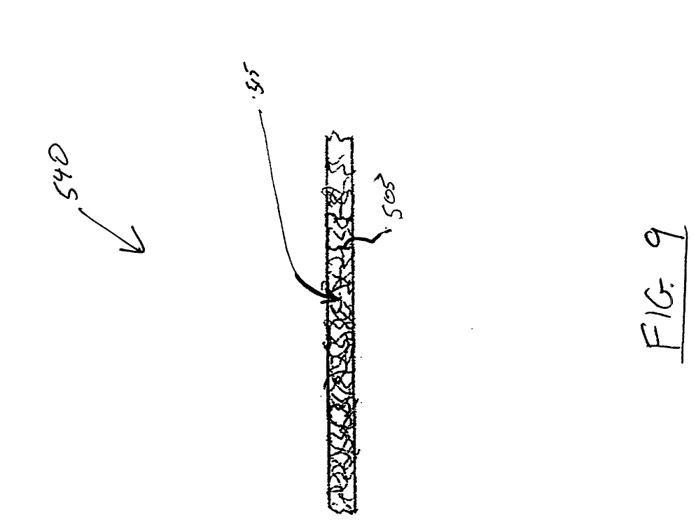

The thickness of the cured foamable compound containing the network of conductive fibers 540 may be controlled by a gap 530 formed between an optional top belt 535 and the bottom belt 510 of the curing section 520. Once the cured foamable compound containing the network of conductive fibers 540 exits the curing section 520, it can then be processed to produce EMI shielding gaskets by peeling, slitting, die cutting, and similar methods. FIG. 9 shows cross-section A-A of FIG. 8 illustrating a cross-sectional profile of the cured product 540.

In yet another embodiment, this invention relates to another method 600 for manufacturing an EMI shield made of conductive particles and a foamable mixture. In one embodiment, conductive particles 605, for example, chopped metal fibers or metallized polymer fibers, are added to the components of a foamable mixture. The components of the foamable mixture can be a polyol component 610 and an isocyonate component 615 of a urethane mixture. The polyol component 610, the isocyonate component 615, and the conductive particles 605 are mixed in one or more mixing heads 625 to produce a urethane mixture with an integral network of conductive particles 620.

The urethane mixture with the integral network of conductive particles 620 is then processed by available means to produce the desired size and shape of a conductive EMI gasket. In one embodiment, the urethane mixture with an integral network of conductive particles 620, is dispensed through a nozzle 630 directly onto a surface 635 of an electrical enclosure 640 using an xyz positioning system 645 to form the EMI gasket in place as the mixture 620 foams and cures.

Alternatives to the above examples include foams of any foamable material with the ability to control viscosity to get good penetration into the conductive web structure, in combination with any elongate conductive material, including chopped foil, chopped metallized polymer, wires, chopped metallized fabric, and grids (e.g., those available from Delker) that can be processed into a web or bead.

Various forms of carbon may be added to urethane foam chemical precursors to produce foams with surface resistivities of 100 to 1000 ohms/square. These materials, however, have limited use in EMI shielding applications, due to the relatively high resistivity. According to the invention, a new process produces conductive foams which are less than 10 ohms/square, and preferably less than 1 ohm/square, by introducing more highly conductive materials into the foam chemical precursors, including silver-plated glass spheres, sintered metal particles which have bulk resistivities below 10⁻⁵ ohm-cm (e.g., those made of Cu, Al, Ni, and Ag), and silver-plated copper particles. Other conductive materials include the class of non-metallic materials referred to as conductive polymers. This would include such materials as poly-Analine.

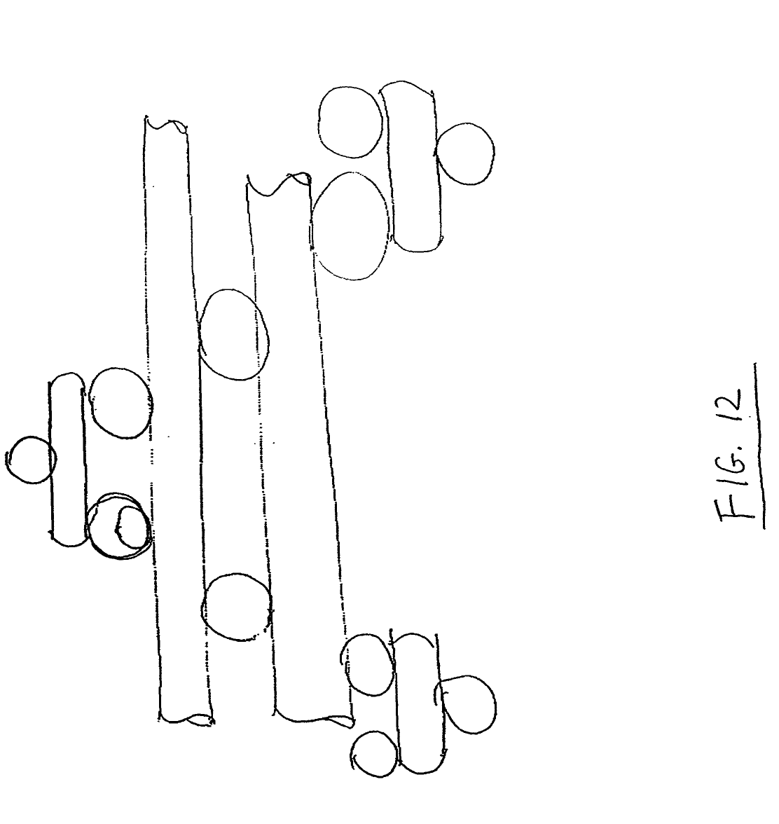

In yet another embodiment, the invention relates to a flexible three-dimensional EMI shielding material which includes a metallized three-dimensional woven or non-woven textile. EMI shielding materials that have surface resistivity below 0.1 ohms/sq., plus the added component of low through resistivity, are needed by the EMI shielding industry. One technique for producing these materials is by metallization of woven or non-woven fabrics that are flexible and can be compressed to 20%-80% of their original height. Any polymeric fiber, including polyester and nylon fibers, may be used to produce the above fabrics. The fabric before metallization may be typically over 0.15 cm (0.060 inches) thick, for example about 0.63 cm (0.25 inches) thick. Fabrics are produced by either random or non-random stacking or weaving of individual fibers to create the desired finished thickness. See, for example, FIG. 12. They are then plated by the following process steps.

Optionally clean the fabric with an alkaline aqueous solution to remove any oils or contaminants. Then create a catalytically active surface on the fabric such that electroless plating can be initiated, for example, by using the method described in U.S. Pat. No. 5,082,734, to electrolessly plate the surface fabric to a resistivity below 10 ohms/sq., for example, using Shipley's 4500 series copper bath. Optionally, put additional electroless or electrolytic metal layers on top of the electroless layer. These additional layers can reduce the resistivity down to as low as about 0.001 ohms/sq. or lower. The additional layers may be used as a cost effective way to reduce resistivity, while imparting desirable environmental, oxidation resistance, and/or galvanic compatibility.

### EXAMPLE 1

Samples of 4 oz/sq.yd. Highloft Polyester non-woven fabric supplied by Kem-wove Inc., located in Charlotte, N.C., was catalytically activated in the manner described in U.S. Pat. No. 5,082,734. The samples were then put in a commercial electroless Cu plating bath supplied by MacDermid Inc. for 15 min. at 35 deg. C. The samples were removed, washed with deionized water, and air-dried at 70 deg. C. for 10 minutes.

The sample exhibited the following properties and characteristics: 0.06 ohms/sq. resistivity (ASTM F390); 1.2 oz/sq.yd. Cu; and 0.25″ final thickness.

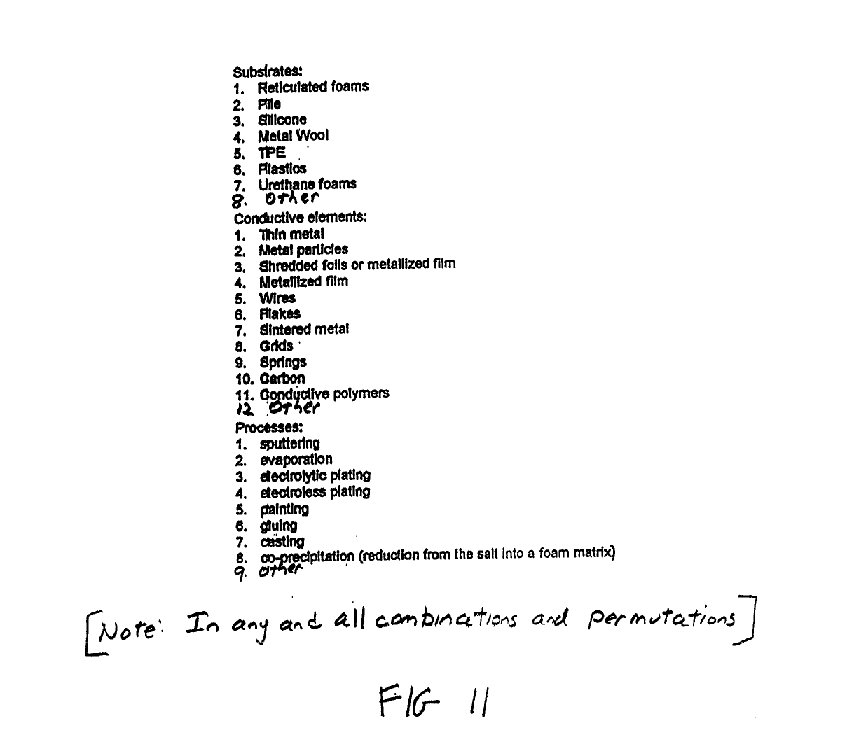

In summary, a wide variety of substrates, conductive elements, and manufacturing processes can be used in various combinations and permutations to manufacture EMI gaskets in accordance with this invention. See, for example, FIG. 11.

Variations, modifications, and other implementations of what is described herein will occur to those of ordinary skill in the art without departing from the spirit and the scope of the invention.

What is claimed is:

1. A method of manufacturing an EMI shield comprising the steps of:
(a) providing a substrate from the group consisting of foam, silicone, thermoplastic elastomer, and urethane foam with a substantially non-porous skin; and
(b) applying a conductive layer to the substrate.

2. The method of claim 1 wherein step (b), applying the conductive layer to the substrate, comprises a vapor deposition process.

3. The method of claim 1 wherein step (b), applying the conductive layer to the substrate, comprises an electroplating process.

4. The method of claim 1 wherein step (b), applying the conductive layer to the substrate, comprises a painting process.

5. The method of claim 1 further comprising the step of cutting the substrate to a desired shape.

6. A method of manufacturing an EMI gasket comprising the steps of:
(a) providing a metal wool web;
(b) applying a foamable mixture to the metal wool web, wherein a viscosity of the foamable mixture is controlled so the foamable mixture permeates at least a portion of the metal wool web before substantial foaming of the foamable mixture begins; and
(c) curing the metal wool web with the permeated foamable mixture.

7. The method of claim 6 further comprising the step of post-processing the metal wool web with the cured foamable mixture.

8. The method of claim 7 wherein the post-processing step comprises cutting the metal wool web with the cured foamable mixture.

9. The method of claim 6 wherein the foamable mixture is a urethane foamable mixture.

10. The method of claim 6 wherein the curing step includes heating.

11. The method of claim 6 wherein the curing step occurs between a first belt and a second belt forming a gap to set at least one of a profile and a thickness for the cured foamable mixture.

12. The method of claim 6 wherein the foamable mixture comprises conductive elements added prior to curing.

13. A method for applying an EMI gasket to a surface of an electrical enclosure comprises the steps of:
mixing conductive particles with foamable materials to form a foam mixture with an integral network of conductive particles; and
processing the foam mixture with the integral network of conductive particles to shape the EMI gasket.

14. The method of claim 13 wherein the foamable materials are a polyol component and an isocyonate component which form a urethane foam mixture.

15. The method of claim 14 wherein the step of processing the urethane foam mixture with the integral network of conductive particles to shape the EMI gasket comprises moving the surface of the electrical enclosure relative to a nozzle supplying the urethane foam with the integral network of conductive particles to form the EMI gasket in place.

16. The method of claim 13 wherein the conductive particles are selected from the group consisting of silver-plated glass spheres, sintered metal particles, silver-plated copper particles, and conductive polymers.

17. The method of claim 16 wherein the sintered metal particles have bulk resistivities below about 10⁻⁵ ohm-cm.

18. A method of manufacturing an EMI shielding device comprising the steps of:
(a) providing a polymeric fiber fabric;
(b) cleaning the polymeric fiber fabric with an alkaline aqueous solution;
(c) creating a catalytically active surface on the polymeric fiber fabric such that electroless plating can be initiated; and
(d) electrolessly plating a surface of the polymeric fiber fabric to a resistivity below about 10 ohms/sq.

19. The method of claim 18 further comprising the step of placing at least one additional metal layer on top of the electrolessly plated surface of the polymeric fiber fabric to yield a resistivity of less than about 0.1 ohms/sq.

20. The method of claim 19 wherein the at least one additional metal layer is selected from the group of an electroless metal layer and an electrolytic metal layer.
